(19) United States
(12) Patent Application Publication
(10) Pub. No.: US 2018/0108786 A1
(43) Pub. Date: Apr. 19, 2018

(54) ARRAY SUBSTRATE, LIQUID CRYSTAL DISPLAY PANEL AND LIQUID CRYSTAL DISPLAY DEVICE

(71) Applicant: Shenzhen China Star Optoelectronics Technology Co., Ltd., Shenzhen, Guangdong (CN)

(72) Inventor: Xiangyang XU, Shenzhen, Guangdong (CN)

(73) Assignee: Shenzhen China Star Optoelectronics Technology Co. , Ltd., Shenzhen, Guangdong (CN)

(21) Appl. No.: 15/110,404

(22) PCT Filed: Jun. 12, 2016
(86) PCT No.: PCT/CN2016/085467

§ 371 Date: Jul. 7, 2016

(30) Foreign Application Priority Data
Mar. 14, 2016 (CN) 201610144317.1

(51) Int. Cl. H01L 29/786; H01L 29/417; G02F 1/1362; G02F 1/1368; H01L 21/02

(52) U.S. Cl. CPC H01L 29/78696; H01L 29/41733; H01L 29/41775; G02F 1/136209; H01L 29/78606; G02F 2001/13606; H01L 29/78618; H01L 21/02244; H01L 21/02178; H01L 21/02255; G02F 1/1368

(57) ABSTRACT

An array substrate, a liquid crystal display panel and a liquid crystal display device are disclosed. The present invention designs that a width of the gate electrode is less than a width of an active layer of a thin-film transistor, and is greater than a width of a channel. Through shortening the width of the gate electrode, decreasing an overlapping region between the source electrode and the gate electrode and between the drain electrode and the gate electrode, a parasitic capacitance between the source electrode, the drain electrode and the gate electrode is reduced in order to increase the display quality.

### BACKGROUND OF THE INVENTION

### 1. Field of the Invention

The present invention relates to a liquid crystal display technology field, and more particularly to an array substrate, a liquid crystal display panel and a liquid crystal display device.

### 2. Description of Related Art

Along with the increase of the size and the definition of a Liquid Crystal Display (LCD), a Thin Film Transistor (TFT) having a Back Channel Etching (BCE) structure is budding and shows a great application prospect. As shown in FIG. 1, the thin-film transistor 10 having the BCE structure includes a gate electrode 12, a gate insulation layer (GI) 13, an active layer 14, a source electrode 15 and a drain electrode 16 which are sequentially formed on an underlying substrate 11. Wherein, the active layer 14 is provided with a channel P of the thin-film transistor 10. A width “c” of the channel P is less than a width “a” of the gate electrode 12 and a width “b” of the active layer 14. The width “a” is greater than the width “b” of the active layer 14 such that when the gate electrode 12 is applied with a voltage, the active layer 14 can provide a carrier flow having sufficient concentration in order to realize a conduction between the source electrode 15 and the drain electrode 16, and when the thin-film transistor 10 is closed, preventing a backlight of a backlight module to irradiate the active layer 14 so as to produce a leakage current. However, in the BCE structure, an overlapping region between the source electrode 15, the drain electrode 16 and the gate electrode 12 is larger so that a parasitic capacitance is larger such that the change of the voltage of the pixel electrode of the liquid crystal device when the thin-film transistor 10 is turned on or off is larger so as to affect the display quality.

### SUMMARY OF THE INVENTION

Accordingly, the present invention provides an array substrate, a liquid crystal display panel and a liquid crystal display device, which can decrease the parasitic capacitance between the source electrode, the drain electrode and the gate electrode in order to increase the display quality.

The array substrate of the present invention provides an array substrate, comprising: an underlying substrate; a gate electrode formed on the underlying substrate; a gate insulation layer formed on the underlying substrate and covering the gate electrode; an active layer formed on the gate insulation layer and located above the gate electrode, wherein, the active layer includes a polysilicon semiconductor layer and an ohmic contact layer which are sequentially formed above the gate insulation layer; a side of the polysilicon semiconductor layer back to the gate electrode is provided with a channel; the ohmic contact layer is located above the channel, and provided with a slit communicated with the channel; an orthographic projection of the active layer on the underlying substrate covers the gate electrode and a portion of the underlying substrate located at two terminals of the gate electrode; an orthographic projection of the channel on the underlying substrate is located inside a region where the gate electrode is located; a protection layer formed on the channel; and a source electrode and a drain electrode formed on the active layer and respectively located at two terminals of the active layer.

Wherein, an orthographic projection of the source electrode on the underlying substrate is partially overlapped with the gate electrode, and an orthographic projection of the drain electrode on the underlying substrate is not overlapped with the gate electrode.

Wherein, an orthographic projection of the drain electrode on the underlying substrate is partially overlapped with the gate electrode, and an orthographic projection of the source electrode on the underlying substrate is not overlapped with the gate electrode.

Wherein, orthographic projections of the source electrode and the drain electrode on the underlying substrate are both not overlapped with the gate electrode.

Wherein, the array substrate further includes: a planarization passivation layer formed on the source electrode, the drain electrode and the active layer, and the planarization passivation layer is provided with a contact hole that reveals a surface of the drain electrode; a pixel electrode formed on the planarization passivation layer and inside the contact hole, and the pixel electrode is electrically connected with the drain electrode through the contact hole.

Wherein, the array substrate further includes: a planarization passivation layer formed on the source electrode, the drain electrode and the active layer, and the planarization passivation layer is provided with a contact hole that reveals a surface of the drain electrode; a common electrode formed on the planarization passivation layer; an insulation layer formed on the common electrode; and a pixel electrode formed on the insulation layer and the planarization passivation layer and inside the contact hole, and the pixel electrode is electrically connected with the drain electrode through the contact hole.

Wherein, a surface of the protection layer includes an Al₂O₃ layer, and the Al₂O₃ layer manufactured by the way that an Al layer formed by magnetron sputtering method, and under a thermal annealing process in a temperature in a range of 300˜400° C. and oxygen concentration higher than 21%.

The present invention provides a liquid crystal display panel, comprising a first substrate and a second substrate disposed oppositely and separately, and liquid crystals filled between the first substrate and the second substrate, wherein, one of the first substrate and the second substrate is an array substrate, and the array substrate comprises: an underlying substrate; a gate electrode formed on the underlying substrate; a gate insulation layer formed on the underlying substrate and covering the gate electrode; an active layer formed on the gate insulation layer and located above the gate electrode, wherein, a side of the active layer back to the gate electrode is provided with a channel; an orthographic projection of the active layer on the underlying substrate covers the gate electrode and a portion of the underlying substrate located at two terminals of the gate electrode; an orthographic projection of the channel on the underlying substrate is located inside a region where the gate electrode is located; and a source electrode and a drain electrode formed on the active layer and respectively located at two terminals of the active layer.

Wherein, the active layer includes a polysilicon semiconductor layer and an ohmic contact layer which are sequentially formed above the gate insulation layer; a side of the polysilicon semiconductor layer back to the gate electrode is provided with a channel; the ohmic contact layer is located above the channel, and provided with a slit communicated with the channel.

Wherein, the array substrate further includes: a planarization passivation layer formed on the source electrode, the drain electrode and the active layer, and the planarization passivation layer is provided with a contact hole that reveals a surface of the drain electrode; a pixel electrode formed on the planarization passivation layer and inside the contact hole, and the pixel electrode is electrically connected with the drain electrode through the contact hole.

Wherein, the array substrate further includes: a planarization passivation layer formed on the source electrode, the drain electrode and the active layer, and the planarization passivation layer is provided with a contact hole that reveals a surface of the drain electrode; a common electrode formed on the planarization passivation layer; an insulation layer formed on the common electrode; and a pixel electrode formed on the insulation layer and the planarization passivation layer and inside the contact hole, and the pixel electrode is electrically connected with the drain electrode through the contact hole.

The present invention provides a liquid crystal display device, comprising a liquid crystal panel and a backlight module for providing light to the liquid crystal display panel, wherein, the array substrate of the liquid crystal display panel includes: an underlying substrate; a gate electrode formed on the underlying substrate; a gate insulation layer formed on the underlying substrate and covering the gate electrode; an active layer formed on the gate insulation layer and located above the gate electrode, wherein, a side of the active layer back to the gate electrode is provided with a channel; an orthographic projection of the active layer on the underlying substrate covers the gate electrode and a portion of the underlying substrate located at two terminals of the gate electrode; an orthographic projection of the channel on the underlying substrate is located inside a region where the gate electrode is located; and a source electrode and a drain electrode formed on the active layer and respectively located at two terminals of the active layer.

Wherein, the active layer includes a polysilicon semiconductor layer and an ohmic contact layer which are sequentially formed above the gate insulation layer; a side of the polysilicon semiconductor layer back to the gate electrode is provided with a channel; the ohmic contact layer is located above the channel, and provided with a slit communicated with the channel.

Wherein, the array substrate further includes: a planarization passivation layer formed on the source electrode, the drain electrode and the active layer, and the planarization passivation layer is provided with a contact hole that reveals a surface of the drain electrode; a pixel electrode formed on the planarization passivation layer and inside the contact hole, and the pixel electrode is electrically connected with the drain electrode through the contact hole.

Wherein, the array substrate further includes: a planarization passivation layer formed on the source electrode, the drain electrode and the active layer, and the planarization passivation layer is provided with a contact hole that reveals a surface of the drain electrode; a common electrode formed on the planarization passivation layer; an insulation layer formed on the common electrode; and a pixel electrode formed on the insulation layer and the planarization passivation layer and inside the contact hole, and the pixel electrode is electrically connected with the drain electrode through the contact hole.

In the array substrate, the liquid crystal display panel and the liquid crystal display device of the embodiment of the present invention, designing that a width of the gate electrode is less than a width of an active layer of a thin-film transistor, and is greater than a width of a channel. Through shortening the width of the gate electrode, decreasing an overlapping region between the source electrode and the gate electrode and between the drain electrode and the gate electrode, a parasitic capacitance between the source electrode, the drain electrode and the gate electrode is reduced in order to increase the display quality.

### BRIEF DESCRIPTION OF THE DRAWINGS

FIG. 1 is a cross-sectional view of a thin-film transistor of an embodiment of the conventional art;

FIG. 2 is a cross-sectional view of an array substrate of an embodiment of the present invention;

FIG. 3 is a cross-sectional view of an array substrate of another embodiment of the present invention;

FIG. 4 is a cross-sectional view of an array substrate of another embodiment of the present invention;

FIG. 5 is a cross-sectional view of a liquid crystal display panel of an embodiment of the present invention; and

FIG. 6 is a cross-sectional view of a liquid crystal display device of an embodiment of the present invention.

### DETAILED DESCRIPTION OF THE PREFERRED EMBODIMENT

The following content combines with the drawings and the embodiment for describing the present invention in detail.

FIG. 2 is a cross-sectional view of an array substrate of an embodiment of the present invention. As shown in FIG. 2, the array substrate 20 (also known as Thin Film Transistor Substrate, or TFT substrate) includes an underlying substrate 21, a thin film transistor 22 formed on the underlying substrate 21, a planarization passivation layer (an over coat layer) 23 and a pixel electrode 24. The thin-film transistor 22 includes a gate electrode 221, a gate insulation layer 222, an active layer 223, a source electrode 224 and a drain electrode 225. Wherein, the gate electrode 221 is formed on the underlying substrate 21; the gate insulation layer 222 is formed on the underlying substrate 21 and covering the gate electrode 221; the active layer 223 is formed on the gate insulation layer 222 and located above the gate electrode 221. A side of the active layer 221 back to the gate electrode 221 is formed with a channel P, and the channel P is a back channel of the thin-film transistor 22. The source electrode 224 and the drain electrode 225 are formed on the active layer 223 and are respectively located at two terminals of the active layer 223. The planarization passivation layer 23 is formed on the source electrode 224, the drain electrode 225, the active layer 223 and the gate insulation layer 222 without covering with the thin-film transistor 22. The planarization passivation layer 23 is provided with a contact hole O₁ that reveals a surface of the drain electrode 225. The pixel electrode 24 is formed on the planarization passivation layer 23 and inside the contact hole O₁. The pixel electrode 24 is electrically connected with the drain electrode 225 of the thin-film transistor 22 through the contact hole O₁.

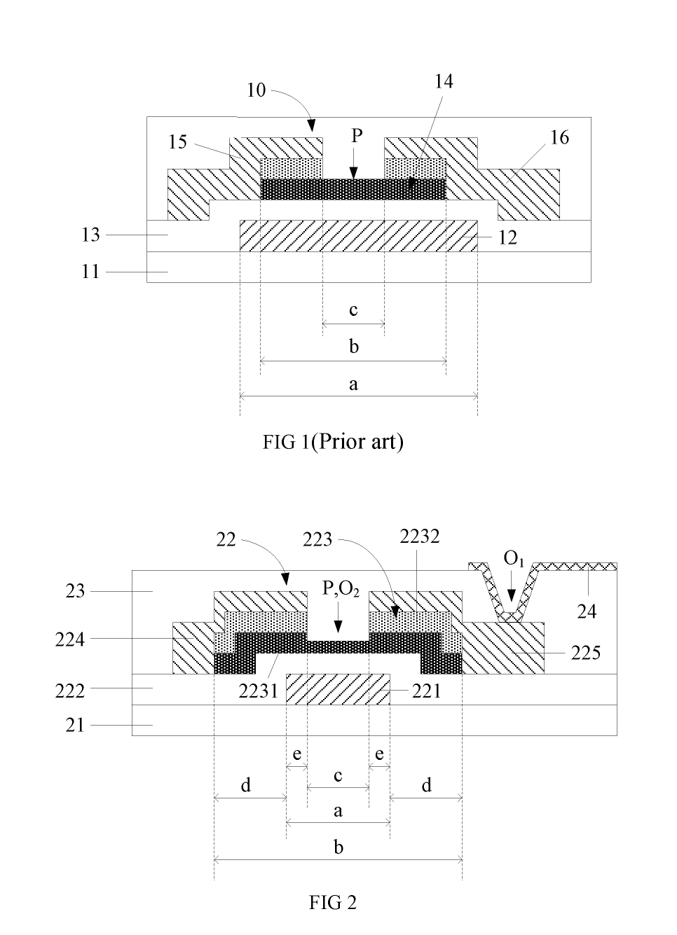

The difference comparing to the conventional technology shown in FIG. 1 is, in the structure of the thin-film transistor 22 of the embodiment of the present invention, an orthographic projection of the active layer 223 on the underlying substrate 21 covers the gate electrode 221 and a portion of the underlying substrate 21 located at two terminals of the gate electrode 221, and an orthographic projection of the channel P on the underlying substrate 21 is located inside a region where the gate electrode 221 is located. Wherein, the orthographic projection means that along a sight direction perpendicular to the underlying substrate 21, projections of the active layer 223 and the channel P on the underlying substrate 21.

With reference to FIG. 2, “a” represents a region corresponding to the gate electrode 221, “b” represents a region corresponding to the active layer 223, “c” represents a region corresponding to the channel P, wherein “a”, “b” and “c” can respectively represent widths of gate electrode 221, the active layer 223 and the channel P along a horizontal direction of the figure. That is, in the embodiment of the present invention, a width “a” of the gate electrode 221 is less than a width “b” of the active layer 223, and is greater than a width “c” of the channel P. That is, “c”<“a”<“c”. Comparing with the conventional art, the embodiment of the present invention, through shortening a width of the gate electrode 221 to reduce a sum of an overlapping region of the source electrode 224 and the gate electrode 221 (an orthographic projection on the underlying substrate 21) and an overlapping region of the drain electrode 225 and the gate electrode 221 (an orthographic projection on the underlying substrate 21) so as to reduce a parasitic capacitance between the gate electrode 224 and the drain electrode 225 and the gate electrode 221 in order to increase the display quality of a liquid crystal display panel and a liquid crystal display device having the array substrate 20.

Besides, the “d” and “e” shown in FIG. 2 shows an ohmic contact region. Wherein, “d” represents a backlight irradiation region, and the “e” represents a gate shielding region. Of course, the “d” and “e” can also represent widths of the backlight irradiation region and the gate shielding region along a horizontal direction of the figure, and e=a−c. When the thin-film transistor 22 is conductive, a voltage is applied on the gate electrode 221 such that the active layer 223 in the region “c” and the region “e” provides carriers. Through the backlight irradiation to be excited such that carrier is provided for the active layer 223 in the region “d” that is not shielded by the gate electrode 221. When the thin-film transistor 22 is turned off, the gate electrode 221 which is light-blocked shields the active layer 223 in order to decrease the leakage current of the thin-film transistor 22 at region “c” and region “d”.

In the present embodiment, the active layer 223 includes a polysilicon (a-Si) semiconductor layer 2231 and an ohmic contact layer 2232 which are sequentially formed on the gate insulation layer 222. Wherein, the ohmic contact layer 2232 includes the region “d” and the region “e”, and the ohmic contact layer 2232 is formed after performing a heavy-doping to the polysilicon semiconductor layer 2231. The polysilicon semiconductor layer includes but not limited to a metal oxide semiconductor layer such as indium gallium oxide (IGZO), indium zinc oxide (IGZO), indium gallium zinc oxide (IGZO), indium tin oxide (ITO). A side of the polysilicon semiconductor layer 2231 back to the gate electrode 221 forms the channel P. The ohmic contact layer 2232 is located above the channel P, and provided with a slit O₂ communicated with the channel P. Because a carrier mobility of a metal oxide semiconductor layer is high, even in the embodiment of the present invention, the structure of the thin-film transistor 22 is designed such that an overlapping region between the drain electrode 224 and the gate electrode 221 and between the drain electrode 225 and the gate electrode 221 is smaller, a conductive channel can still be formed in the active layer 223.

The main purpose of the embodiment of the present invention is designing the width “a” of the gate electrode 221 to be less than the width “b” of the active layer 223 in order to decrease an overlapping region between the source electrode 224 and the gate electrode 221 and between the drain electrode 225 and the gate electrode 221. The core is that the width “a” of the gate electrode 221 is less than the width “b” of the active layer 223, and the widths of the source electrode 224 and the drain electrode 225 are not limited. Of course, in order to further reduce an overlapping region between the source electrode 224 and the gate electrode 221 and between the drain electrode 225 and the gate electrode 221, the embodiment of the present invention can adopt another design based on the above. For example, the first kind, an orthographic projection of the source electrode 224 on the underlying substrate 21 is partially overlapped with the gate electrode 221, and an orthographic projection of the drain electrode 225 on the underlying substrate 21 is not overlapped with the gate electrode 221; the second kind, an orthographic projection of the drain electrode 225 on the underlying substrate 21 is partially overlapped with the gate electrode 221, and an orthographic projection of the source electrode 224 on the underlying substrate 21 is not overlapped with the gate electrode 221; the third kind, orthographic projections of the source electrode 224 and the drain electrode 225 on the underlying substrate 21 are both not overlapped with the gate electrode 221.

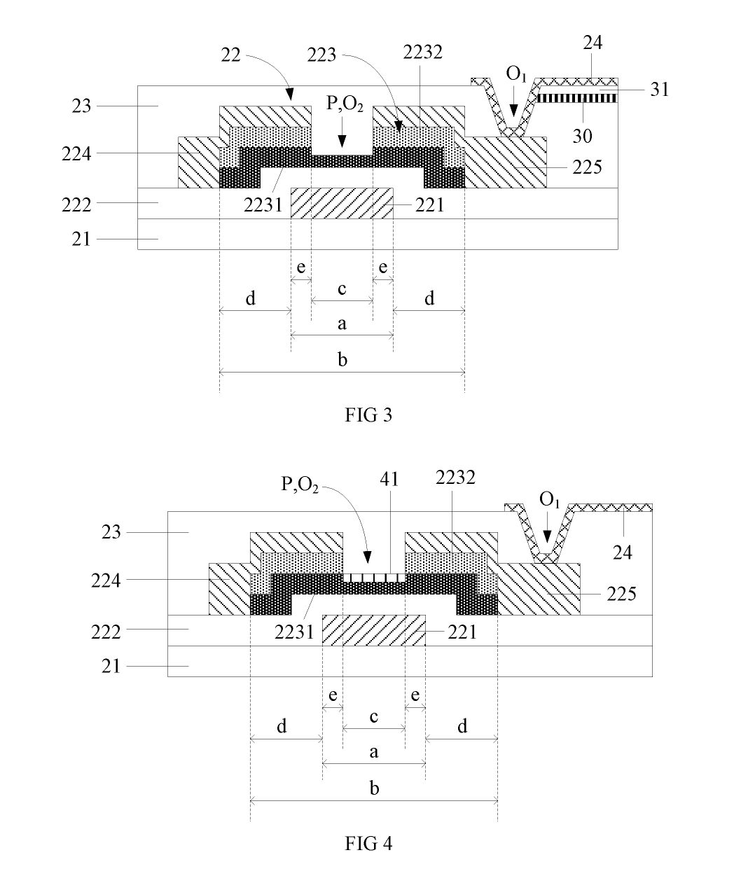

Of course, the array substrate 20 also includes other structures of the conventional art such as a common electrode formed in the array substrate 20 and a protection layer located between the common electrode and the pixel electrode 24. FIG. 3 is a cross-sectional view of an array substrate of another embodiment of the present invention. In order to describe the difference between the embodiments, the same elements adopt same numerals. As shown in FIG. 3, the difference comparing to the embodiment shown in FIG. 2 is, the array substrate 20 of the present embodiment further includes a common electrode 30 and an insulation layer 31 formed between the planarization passivation layer 23 and the pixel electrode 24. That is, the common electrode layer 30 is formed on the planarization passivation layer 23, and the insulation layer 31 is formed on the common electrode layer 30. Wherein, the insulation layer 31 is also known as a PV (Passivation) layer. The pixel electrode 24 is formed on the insulation layer 31 and the planarization passivation layer 23, and inside the contact hole O₁. The pixel electrode 24 is electrically connected with the drain electrode 225 of the thin-film transistor 22 through the contact hole O₁.

FIG. 4 is a cross-sectional view of an array substrate of another embodiment of the present invention. In order to describe the difference between the embodiments, the same elements adopt same numerals. As shown in FIG. 4, the difference comparing to the embodiment shown in FIG. 2 is, the array substrate 20 of the present embodiment further includes a protection layer 41 formed on the channel P. Because the semiconductor that forms the channel P is a sensitive to water and oxygen, the water and oxygen is easily to affect the electric performance of the channel P. Accordingly, in order to increase the electric stability of the channel P, a protection layer 41 is required to form on the channel P. The protection layer 41 can also called as a water and oxygen isolation layer or an etch stop layer (ESL).

The material of the protection layer 41 includes but not limited to silicon oxide SiO₂ and silicon nitride Si₃N₄, and can be manufactured through a chemical vapor deposition (CVD) method, an atom layer deposition (ALD) method or a magnetron sputtering method.

Of course, a surface of the protection layer 41 can also include a Al₂O₃ layer, and the Al₂O₃ layer can be manufactured by the way that an Al layer formed by magnetron sputtering method, and under a thermal annealing process at a temperature in a range of 300˜400° C. and oxygen concentration higher than 21% such that the Al₂O₃ layer can be manufactured maximally. At the same time, the temperature of 300˜400° C. can induce the oxidation reaction so that the Al atoms in the Al layer can be oxidized as many as possible in order to ensure the densification of the Al₂O₃ layer such that the film quality is higher in order to ensure the electric performance of the channel P. Beside, performing the thermal annealing process in an environment full of oxygen has three functions at the same time: first, decreasing the density of defects of the P channel in order to obtain a good electric performance of the active layer; second, fixing the damage of the channel P caused by magnetron sputtering process or etching process in a deposition and patterning process of the active layer 223; third, oxidizing the Al layer to be an Al₂O₃ layer having a higher film quality in order to form a better channel protection layer.

The embodiment of the present also provides a liquid crystal display panel as shown in FIG. 5. As shown in FIG. 5, the liquid crystal display panel 50 includes an array substrate 51 and a color filter (CF) substrate 52 disposed oppositely and separately, and liquid crystals (liquid crystal molecules) 53 filled between the array substrate 51 and the color filter substrate 52. Wherein, the liquid crystals are located inside a liquid crystal cell overlapped and combined by the array substrate 51 and the color filter substrate 52. The array substrate 51 includes anyone of the array substrate 20 described in the above embodiment. According, the beneficial effects are the same.

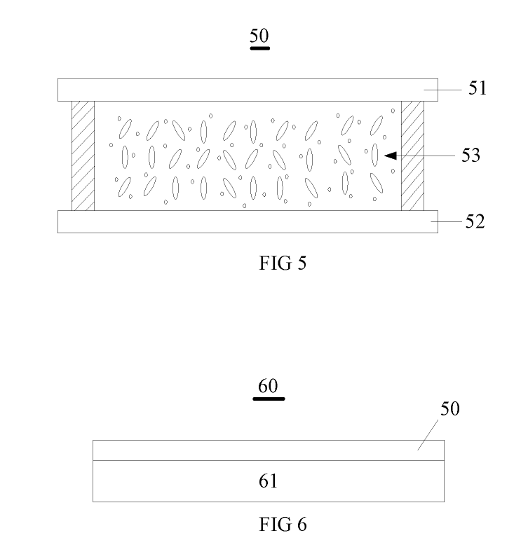

The embodiment of the present invention also provides a liquid crystal display device 60 as shown in FIG. 6, the liquid crystal display device 60 includes a liquid crystal display panel 50 and a backlight module for providing light to the liquid crystal display panel. Because the liquid crystal display device 60 also has the array substrate 20 as designed above, the beneficial effects are the same.

The above embodiments of the present invention are not used to limit the claims of this invention. Any use of the content in the specification or in the drawings of the present invention which produces equivalent structures or equivalent processes, or directly or indirectly used in other related technical fields is still covered by the claims in the present invention.

What is claimed is:

1. An array substrate, comprising:
an underlying substrate;
a gate electrode formed on the underlying substrate;
a gate insulation layer formed on the underlying substrate and covering the gate electrode;
an active layer formed on the gate insulation layer and located above the gate electrode, wherein, the active layer includes a polysilicon semiconductor layer and an ohmic contact layer which are sequentially formed above the gate insulation layer; a side of the polysilicon semiconductor layer back to the gate electrode is provided with a channel; the ohmic contact layer is located above the channel, and provided with a slit communicated with the channel; an orthographic projection of the active layer on the underlying substrate covers the gate electrode and a portion of the underlying substrate located at two terminals of the gate electrode; an orthographic projection of the channel on the underlying substrate is located inside a region where the gate electrode is located;
a protection layer formed on the channel; and
a source electrode and a drain electrode formed on the active layer and respectively located at two terminals of the active layer.

2. The array substrate according to claim 1, wherein, an orthographic projection of the source electrode on the underlying substrate is partially overlapped with the gate electrode, and an orthographic projection of the drain electrode on the underlying substrate is not overlapped with the gate electrode.

3. The array substrate according to claim 1, wherein, an orthographic projection of the drain electrode on the underlying substrate is partially overlapped with the gate electrode, and an orthographic projection of the source electrode on the underlying substrate is not overlapped with the gate electrode.

4. The array substrate according to claim 1, wherein, orthographic projections of the source electrode and the drain electrode on the underlying substrate are both not overlapped with the gate electrode.

5. The array substrate according to claim 1, wherein, the array substrate further includes:
a planarization passivation layer formed on the source electrode, the drain electrode and the active layer, and the planarization passivation layer is provided with a contact hole that reveals a surface of the drain electrode;
a pixel electrode formed on the planarization passivation layer and inside the contact hole, and the pixel electrode is electrically connected with the drain electrode through the contact hole.

6. The array substrate according to claim 1, wherein, the array substrate further includes:
a planarization passivation layer formed on the source electrode, the drain electrode and the active layer, and the planarization passivation layer is provided with a contact hole that reveals a surface of the drain electrode;
a common electrode formed on the planarization passivation layer;
an insulation layer formed on the common electrode; and
a pixel electrode formed on the insulation layer and the planarization passivation layer and inside the contact hole, and the pixel electrode is electrically connected with the drain electrode through the contact hole.

7. The array substrate according to claim 1, wherein, a surface of the protection layer includes an Al₂O₃ layer, and the Al₂O₃ layer is manufactured by the way that an Al layer formed by magnetron sputtering method, and under a thermal annealing process at a temperature in a range of 300˜400° C. and oxygen concentration higher than 21%.

8. A liquid crystal display panel, comprising a first substrate and a second substrate disposed oppositely and separately, and liquid crystals filled between the first substrate and the second substrate, wherein, one of the first substrate and the second substrate is an array substrate, and the array substrate comprises:
an underlying substrate;
a gate electrode formed on the underlying substrate;
a gate insulation layer formed on the underlying substrate and covering the gate electrode;
an active layer formed on the gate insulation layer and located above the gate electrode, wherein, a side of the active layer back to the gate electrode is provided with a channel; an orthographic projection of the active layer on the underlying substrate covers the gate electrode and a portion of the underlying substrate located at two terminals of the gate electrode; an orthographic projection of the channel on the underlying substrate is located inside a region where the gate electrode is located; and
a source electrode and a drain electrode formed on the active layer and respectively located at two terminals of the active layer.

9. The liquid crystal display panel according to claim 8, wherein, the active layer includes a polysilicon semiconductor layer and an ohmic contact layer which are sequentially formed above the gate insulation layer; a side of the polysilicon semiconductor layer back to the gate electrode is provided with a channel; the ohmic contact layer is located above the channel, and provided with a slit communicated with the channel.

10. The liquid crystal display panel according to claim 8, wherein, the array substrate further includes:
a planarization passivation layer formed on the source electrode, the drain electrode and the active layer, and the planarization passivation layer is provided with a contact hole that reveals a surface of the drain electrode; and
a pixel electrode formed on the planarization passivation layer and inside the contact hole, and the pixel electrode is electrically connected with the drain electrode through the contact hole.

11. The liquid crystal display panel according to claim 8, wherein, the array substrate further includes:
a planarization passivation layer formed on the source electrode, the drain electrode and the active layer, and the planarization passivation layer is provided with a contact hole that reveals a surface of the drain electrode;
a common electrode formed on the planarization passivation layer;
an insulation layer formed on the common electrode; and
a pixel electrode formed on the insulation layer and the planarization passivation layer and inside the contact hole, and the pixel electrode is electrically connected with the drain electrode through the contact hole.

12. A liquid crystal display device, comprising a liquid crystal panel and a backlight module for providing light to the liquid crystal display panel, wherein, the array substrate of the liquid crystal display panel includes:
an underlying substrate;
a gate electrode formed on the underlying substrate;
a gate insulation layer formed on the underlying substrate and covering the gate electrode;
an active layer formed on the gate insulation layer and located above the gate electrode, wherein, a side of the active layer back to the gate electrode is provided with a channel; an orthographic projection of the active layer on the underlying substrate covers the gate electrode and a portion of the underlying substrate located at two terminals of the gate electrode; an orthographic projection of the channel on the underlying substrate is located inside a region where the gate electrode is located; and
a source electrode and a drain electrode formed on the active layer and respectively located at two terminals of the active layer.

13. The liquid crystal display device according to claim 12, wherein, the active layer includes a polysilicon semiconductor layer and an ohmic contact layer which are sequentially formed above the gate insulation layer; a side of the polysilicon semiconductor layer back to the gate electrode is provided with a channel; the ohmic contact layer is located above the channel, and provided with a slit communicated with the channel.

14. The liquid crystal display device according to claim 12, wherein, the array substrate further includes:
a planarization passivation layer formed on the source electrode, the drain electrode and the active layer, and the planarization passivation layer is provided with a contact hole that reveals a surface of the drain electrode; and
a pixel electrode formed on the planarization passivation layer and inside the contact hole, and the pixel electrode is electrically connected with the drain electrode through the contact hole.

15. The liquid crystal display device according to claim 12, wherein, the array substrate further includes:
a planarization passivation layer formed on the source electrode, the drain electrode and the active layer, and the planarization passivation layer is provided with a contact hole that reveals a surface of the drain electrode;
a common electrode formed on the planarization passivation layer;
an insulation layer formed on the common electrode; and
a pixel electrode formed on the insulation layer and the planarization passivation layer and inside the contact hole, and the pixel electrode is electrically connected with the drain electrode through the contact hole.
